(19) United States
(12) Patent Application Publication
(10) Pub. No.: US 2009/0311521 A1
(43) Pub. Date: Dec. 17, 2009

(54) THIN FILM AND OPTICAL INTERFERENCE FILTER INCORPORATING HIGH-INDEX TITANIUM DIOXIDE AND METHOD FOR MAKING THEM

(76) Inventors: ANGUEL NIKOLOV, Los Angeles, CA (US); David W. Cunningham, Los Angeles, CA (US)

Correspondence Address: SHEPPARD, MULLIN, RICHTER & HAMPTON LLP, 333 SOUTH HOPE STREET, 48TH FLOOR, LOS ANGELES, CA, 90071-1448, US

(21) Appl. No.: 12/481,778

(22) Filed: Jun. 10, 2009

Related U.S. Application Data
(60) Provisional application No. 61/061,080, filed on Jun. 12, 2008.

(51) Int. Cl. B32B 7/02; B32B 9/04; C23C 16/44; B05D 5/06; B32B 17/06

(52) U.S. Cl. 428/336; 428/701; 427/248.1; 428/332; 427/162; 428/432

(57) ABSTRACT

The present invention pertains generally to a high-index film deposited on a substrate, the film comprising a layer of a prescribed seed material and an overlaying layer of titanium dioxide (TiO₂). The seed material has a prescribed, uniform inter-atomic spacing adapted to cause the overlaying TiO₂ to have a high-index phase. The present invention also pertains generally to a method for forming a high-index film, comprising the steps of first forming a layer of a seed material having the prescribed, uniform inter-atomic spacing, and then forming a layer of TiO₂ atop the seed material, such that the TiO₂ has the high-index phase.

### CROSS-REFERENCE TO RELATED APPLICATION

Priority is claimed to U.S. Provisional Application Ser. No. 61/061,080, filed on Jun. 12, 2008, the contents of which are incorporated by reference in their entirety.

### BACKGROUND OF THE INVENTION

This invention relates generally to optical coatings and, more particularly, to optical coatings incorporating films of high-index titanium dioxide (TiO₂) and to methods for making such films and coatings.

Dielectric coatings for optical interference filters generally comprise alternating layers of a material having a high refractive index and a material having a low refractive index, the alternating layers deposited on a substrate such as glass. It is desirable to have as large a difference as possible between the high and low refractive index values to make an effective filter and to minimize the thickness and production cost of a coating having a desired spectral performance. It is also desirable to use materials that exhibit as little absorption and scattering as possible in the wavelength range of interest in order to optimize transmission and reflection.

Filters have been produced using atomic layer deposition (ALD) for a limited number of optical applications that require relatively thick coatings. ALD is a slow and expensive process for thick coatings, but ALD is useful if precise layer thickness and minimal defects are required. TiO₂ has been used in ALD optical filters, because TiO₂ has a high index of refraction (typically about 2.40 when deposited at about 300° C. from titanium tetrachloride (TiCl₄) and H₂O precursors). However, because TiO₂ tends to crystallize readily above 150° C., and consequently exhibits greater scattering and absorption, TiO₂ is often laminated with other materials, such as aluminum oxide (Al₂O₃), to limit crystal size and reduce scattering (see U.S. Patent Application Publication No. 2006/0134433 A1).

Prior art work based upon lamination of thin TiO₂ layers takes advantage of the property of TiO₂ to remain amorphous for relatively thin layers when grown on a “randomly” ordered surface or on a surface having a significantly different crystal lattice. If the deposited TiO₂ layer thickness exceeds 10 to 20 nanometers (nm), however, the film starts to form a polycrystalline phase having a grain structure. The grains scatter light propagating though the film and lead to optical losses. If the TiO₂ is kept amorphous by limiting layer thickness with nano-lamination, the polycrystalline phase will not form, and the films will retain optical transparency.

Unfortunately, there are two problems with the nano-lamination approach. First, the laminating material reduces the average refractive index of the high-index layer in which the laminating material is incorporated, since the laminating material has a relatively low refractive index. For example, Al₂O₃ has a refractive index of only about 1.644 at 633 nm. Second, an amorphous film has a lower packing density, higher coefficient of thermal expansion (CTE), and lower index of refraction than a mono-crystalline film comprising the same molecules. The nano-laminated TiO₂ that is used for ALD optical filters is generally deposited on substrates at temperatures in the range of 270 to 350° C. These temperatures produce films that are primarily amorphous and that have a moderate density and a moderate composite index of refraction. TiO₂ films deposited by ALD at temperatures less than about 150° C. tend to have a low packing density, a low index of refraction, and high tensile stress.

There is thus a need for a high-index material for use in an interference filter, the high-index material having a high index value (n), a low absorption coefficient (k), and low scattering. There is also a need for a method for producing such a high-index material. The present invention provides such a high-index material and a method for producing it.

### SUMMARY OF THE INVENTION

The present invention pertains generally to a thin film and optical interference filter incorporating a high-index titanium dioxide material. The film comprises a layer of a seed material having a prescribed, uniform inter-atomic spacing and a layer of TiO₂ deposited on the layer of seed material. The seed material has a prescribed, uniform inter-atomic spacing adapted to cause the overlaying TiO₂ to have a high-index phase. The present invention also pertains generally to a method for forming a high-index film, the method comprising forming a layer of a seed material having the prescribed, uniform inter-atomic spacing and forming over the layer of seed material a layer of TiO₂ in the high-index phase.

In one embodiment, the present invention encompasses a high-index film comprising a layer of a seed material and a layer of TiO₂ deposited on the layer of the seed material, wherein the film has a refractive index of at least 2.55 and an absorption coefficient of at most 1×10⁻⁴, at a wavelength of 633 nm. The present invention also encompasses a method for forming high-index film having a refractive index of at least 2.55 and an absorption coefficient of at most 1×10⁻⁴, at a wavelength of 633 nm, the method comprising forming a layer of a seed material and forming a layer of TiO₂ on the layer of the seed material. The seed material preferably is selected from the group consisting of zirconium dioxide (ZrO₂) and hafnium dioxide (HfO₂).

In one particular embodiment, the present invention pertains to a film comprising TiO₂ in a primarily mono-crystalline (rutile) phase with minimum threading dislocations and crystal defects (which lead to optical losses). The present invention also pertains to a method for growing TiO₂ on an arbitrary starting material surface in a primarily rutile phase with minimum threading dislocations and crystal defects.

In another embodiment, the present invention pertains to an optical filter comprising a plurality of layers having a low refractive index interleaved with a plurality of layers having a high refractive index deposited onto a substrate. Each of the plurality of the high-index layers comprises a layer of seed material and a layer of titanium dioxide deposited on the layer of seed material. The seed material has a prescribed, uniform inter-atomic spacing adapted to cause the overlaying layer of titanium dioxide to be deposited in a primarily rutile phase. In the optical filter of the invention, each of the plurality of high refractive index layers preferably has a refractive index of at least 2.55 and an absorption coefficient of at most 1×10⁻⁴, at a wavelength of 633 nm.

The present invention also pertains to a method for forming such an optical filter, comprising the steps of providing a substrate and depositing a thin film on the substrate, including a plurality of steps of depositing a layer of material having a low refractive index interleaved with a plurality of steps of depositing a layer of material having a high refractive index. Each of the plurality of steps of depositing a layer of material having a high refractive index comprises the steps of depositing a layer of a seed material and depositing a layer of titanium dioxide onto the layer of seed material. The layer of seed material and the layer of titanium, together, comprise the layer of high refractive index material. The layer of seed material has a prescribed, uniform inter-atomic spacing adapted to cause the overlaying layer of titanium dioxide to be deposited in a primarily rutile phase.

In more detailed features of the invention, the number of ALD cycles used to deposit each ZrO₂ seed layer preferably is more than seven, more preferably is in the range of seven to 28, and most preferably is in the range of about 14 to about 18. In addition, the TiO₂ layer preferably has a thickness less than 80 nm, or more preferably less than 20 nm, and most preferably less than 10 nm.

Other features and advantages of the present invention should become apparent from the following description of the preferred embodiment, taken in conjunction with the accompanying drawings, which illustrate, by way of example, the principles of the invention.

### BRIEF DESCRIPTION OF THE DRAWINGS

FIG. 1A is a side sectional view of a high-index TiO₂/ZrO₂ film, in accordance with an embodiment of the present invention.

FIG. 1B is a side sectional view of an optical filter comprising a high-index TiO₂/ZrO₂ film, in accordance with an embodiment of the present invention.

FIG. 2 is a graph depicting the refractive index as a function of wavelength of two TiO₂/ZrO₂ films in accordance with embodiments of the present invention, one film having ZrO₂ layers that are seven ALD cycles thick and the other film having ZrO₂ layers that are 14 ALD cycles thick.

FIG. 3 is a graph depicting the refractive index as a function of wavelength of two films, one film having 1400 ALD cycles of TiO₂ and the other film having 1400 ALD cycles of TiO₂ atop a seed layer of 14 ALD cycles of ZrO₂ in accordance with an embodiment of the present invention.

FIG. 4A is a table showing measured and calculated data for several coatings incorporating TiO₂ and ZrO₂, deposited at a temperature of 475° C. For each coating, the data includes the combined thickness in nanometers of the ZrO₂ layers (t_{Z}); the calculated refractive index of the ZrO₂ layers at 633 nm (n_{Z}); the combined thickness in nanometers of the TiO₂ layers (t_{T}); the calculated refractive index of the TiO₂ layers at 633 nm (n_{T}); the combined thickness in nanometers of the ZrO₂ and TiO₂ layers (t_{TZ}); the composite refractive index of the ZrO₂ and TiO₂ layers at 633 nm (n_{TZ}); the absorption coefficient of the combined ZrO₂ and TiO₂ layers (k_{TZ}); and the percentage change in peak optical transmission of the combined ZrO₂ and TiO₂ layers after baking for 70 hours at 950° C. (ΔT).

FIG. 4B is a table showing measured and calculated data for several coatings incorporating TiO₂ and ZrO₂, deposited at a temperature of 475° C. For each coating, the data includes the combined thickness in nanometers of the ZrO₂ layers (t_{Z}); the calculated refractive index of the ZrO₂ layers at 633 nm (n_{Z}); the combined thickness in nanometers of the TiO₂ layers (t_{T}); the calculated refractive index of the TiO₂ layers at 633 nm (n_{T}); the combined thickness in nanometers of the ZrO₂ and TiO₂ layers (t_{TZ}); the composite refractive index of the ZrO₂ and TiO₂ layers at 633 nm (n_{TZ}); and the absorption coefficient of the combined ZrO₂ and TiO₂ layers (k_{TZ}).

FIG. 5 is a table showing measured and calculated data for coatings deposited on various substrates. Each coating includes eight layers of TiO₂ and ZrO₂, with each layer having 14 ALD cycles of ZrO₂ followed by 165 ALD cycles of TiO₂, deposited at a temperature of 520° C. For each coating, the data includes the combined thickness in nanometers of the ZrO₂ layers (t_{Z}); the calculated refractive index of the ZrO₂ layers at 633 nm (n_{Z}); the combined thickness in nanometers of the TiO₂ layers (t_{T}); the calculated refractive index of the TiO₂ layers at 633 nm (n_{T}); the combined thickness in nanometers of the ZrO₂ and TiO₂ layers (t_{TZ}); the composite refractive index of the ZrO₂ and TiO₂ layers at 633 nm (n_{TZ}); and the absorption coefficient of the combined ZrO₂ and TiO₂ layers (k₆₃₃).

FIG. 6 is a graph showing optical transmission as a function of wavelength of 1400 ALD cycles of TiO₂, after deposition at 475° C. (AD) and after baking for 70 hours at 950° C.

FIG. 7 is a graph showing optical transmission as a function of wavelength of 1400 ALD cycles of TiO₂ and 14 ALD cycles of ZrO₂, after deposition at 475° C. (AD) and after baking for 70 hours at 950° C.

FIG. 8 is a schematic diagram depicting the crystal structure of the rutile phase of TiO₂.

FIG. 9 is a graph showing the x-ray diffraction pattern of a sample of 1400 ALD cycles of TiO₂ deposited on 14 ALD cycles of ZrO₂, in accordance with an embodiment of the present invention.

### DETAILED DESCRIPTION OF THE PREFERRED EMBODIMENTS

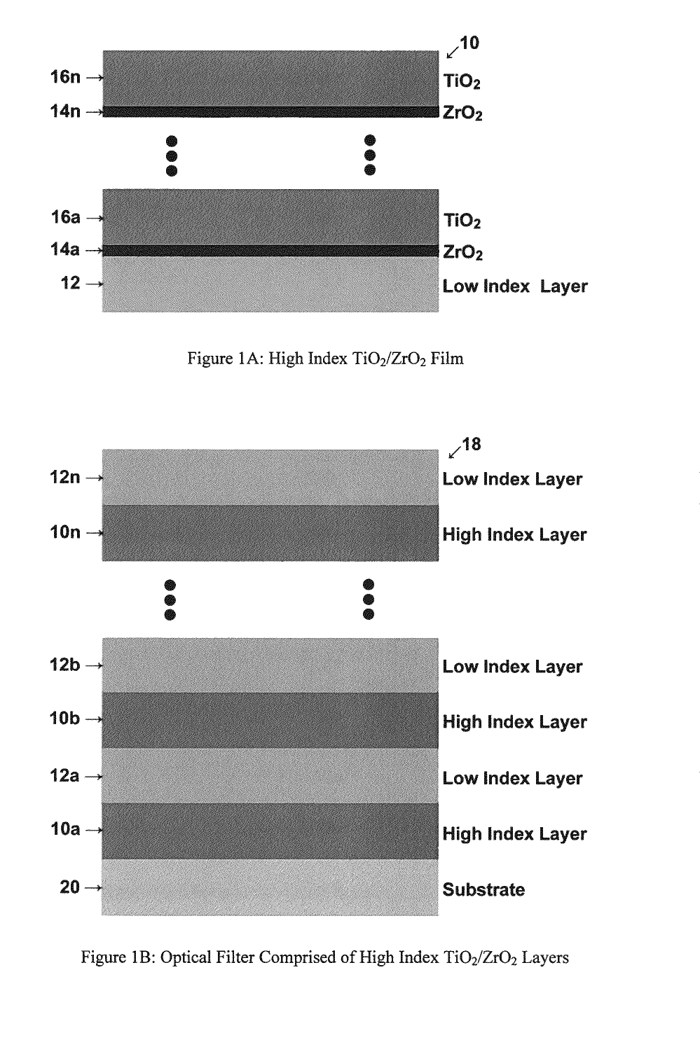

With reference now to the accompanying drawings, and particularly to FIG. 1A, there is shown a side sectional view of a high-index TiO₂/ZrO₂ film 10 in accordance with one preferred embodiment of the present invention, the film incorporating a plurality of ZrO₂ layers (14a-14n) interleaved with a plurality of TiO₂ layers (16a-16n). The first ZrO₂ layer 14a is formed atop a low index substrate layer 12, and the first TiO₂ layer 16a is formed atop the first ZrO₂ layer 14a. Subsequent alternating layers of ZrO₂ and TiO₂ may be formed atop the first ZrO₂ and TiO₂ layers, culminating in the final ZrO₂ layer 14n and final TiO₂ layer 16n. The present invention encompasses any number of alternating ZrO₂ layers and TiO₂ layers, including only one ZrO₂ layer and only one TiO₂ layer.

The ZrO₂ layers 14a-14n and TiO₂ layers 16a-16n all are deposited using atomic layer deposition (ALD). The ZrO₂ layers preferably are substantially thinner than are the TiO₂ layers. The TiO₂ layers 16a-16n are grown using titanium chloride (TiCl₄) and H₂O precursors, at substrate temperatures in the temperature range of about 450 to 500° C. on the thin ZrO₂ seed layers 14a-14n. In this way, a high index of refraction and low absorption coefficient can be achieved.

With reference now to FIG. 1B, there is shown a side sectional view of an optical interference filter 18 comprising a plurality of layers having a high refractive index (10a-10n) interleaved with a plurality of layers having a low refractive index (12a-12n) deposited on a substrate 20. Each of the plurality of high-index layers comprises a TiO₂/ZrO₂ film 10 like that depicted in FIG. 1A.

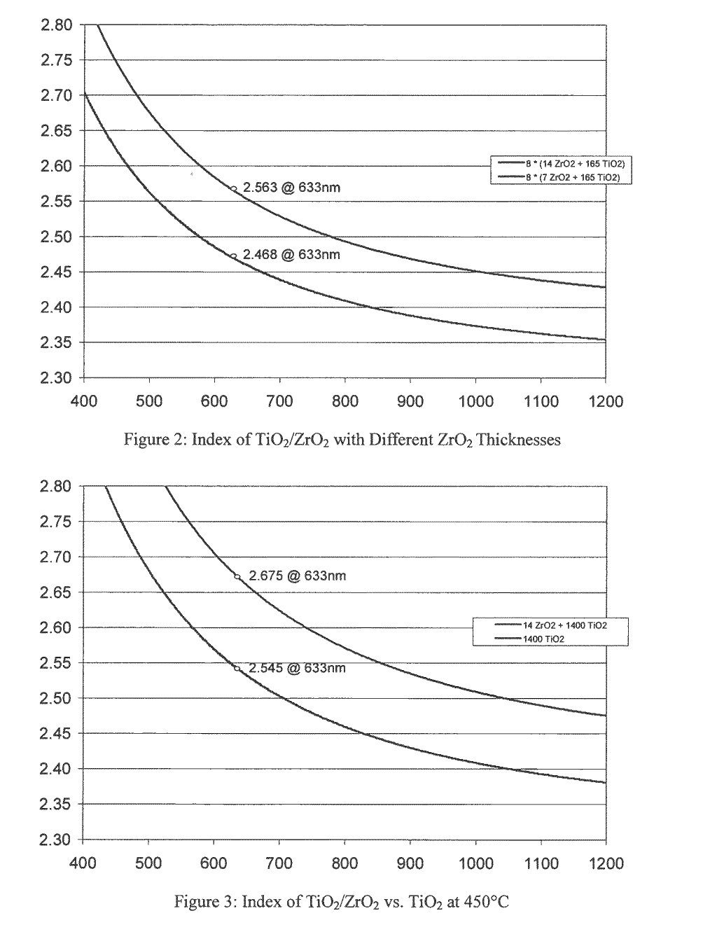

FIG. 2 is graph depicting the refractive index as a function of wavelength of two TiO₂/ZrO₂ films in accordance with the present invention, deposited using ALD. One film includes ZrO₂ layers that are each 7 ALD cycles thick, and the other film includes ZrO₂ layers that are 14 ALD cycles thick. The film that includes 14-cycle ZrO₂ layers has a higher composite refractive index than does the film having 7-cycle ZrO₂ layers, despite the fact that ZrO₂ generally has a lower index of refraction than does TiO₂.

FIG. 3 is a graph depicting the refractive index as a function of wavelength of two TiO₂/ZrO₂ films, deposited using ALD. One film includes 1400 ALD cycles of TiO₂, and the other film includes 1400 ALD cycles of TiO₂ atop a seed layer of 14 ALD cycles of ZrO₂. The film that includes the seed layer of 14 cycles of ZrO₂ has a higher composite refractive index that does the film lacking the ZrO₂ seed layer.

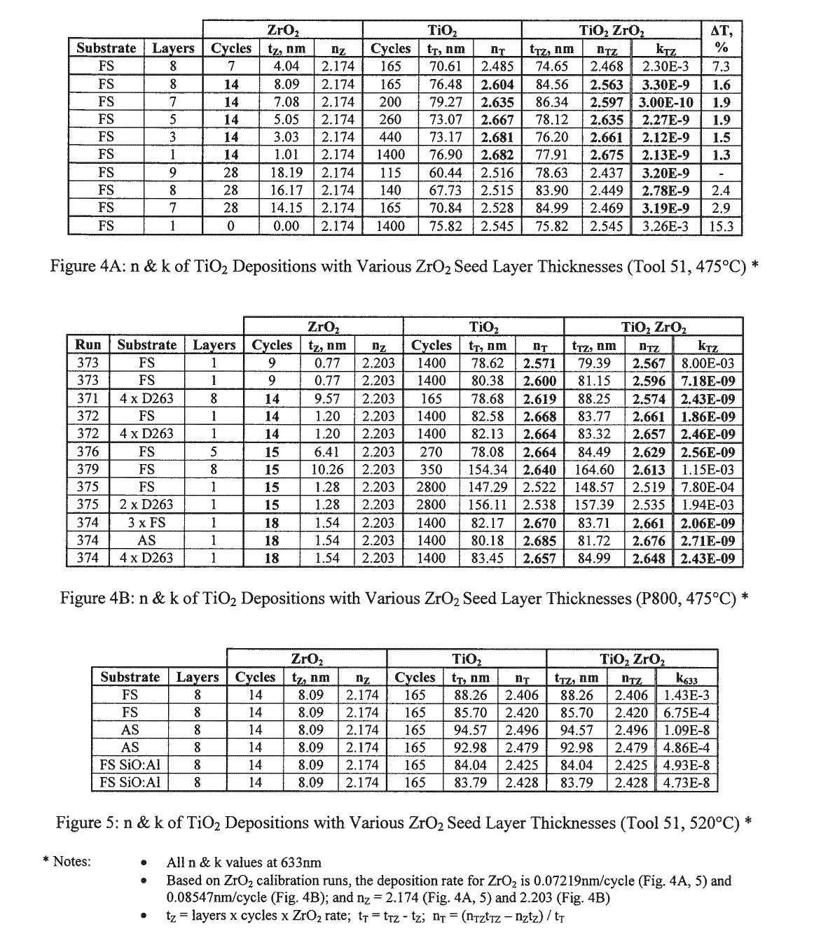

With reference now to FIG. 4A, there is shown a table setting forth measured and calculated data for several TiO₂/ZrO₂ coatings in accordance with the present invention, deposited on a fused silica substrate at a temperature of 475° C. For each coating, the data includes the combined thickness in nanometers of the ZrO₂ layers (t_{Z}); the calculated refractive index of the ZrO₂ layers at 633 nm (n_{Z}); the combined thickness in nanometers of the TiO₂ layers (t_{T}); the calculated refractive index of the TiO₂ layers at 633 nm (n_{T}); the combined thickness in nanometers of the ZrO₂ and TiO₂ layers (t_{TZ}); the composite refractive index of the ZrO₂ and TiO₂ layers at 633 nm (n_{TZ}); the absorption coefficient of the combined ZrO₂ and TiO₂ layers (k_{TZ}); and the percentage change in peak optical transmission of the combined ZrO₂ and TiO₂ layers after baking for 70 hours at 950° C. (ΔT).

As shown in FIG. 4A, the calculated refractive index of the TiO₂ increases from 2.485 for the coating incorporating seven ALD cycles of ZrO₂ to 2.604 for the coating incorporating 14 ALD cycles of ZrO₂. When the number of cycles of ZrO₂ is increased to 28, however, the calculated refractive index of the TiO₂ is observed to decrease substantially. Also as shown in FIG. 4A, the refractive index of 1400 ALD cycles of pure TiO₂, deposited at 475° C., is 2.545 at 633 nm. This refractive index increases to 2.675 when the 1400 ALD cycles of TiO₂ are grown on a seed layer of 14 ALD cycles of ZrO₂. Thus, despite the fact that ZrO₂ generally has a lower index of refraction than that of TiO₂, the presence of the seed layer of 14 ALD cycles of ZrO₂ can raise the refractive index of a film containing TiO₂.

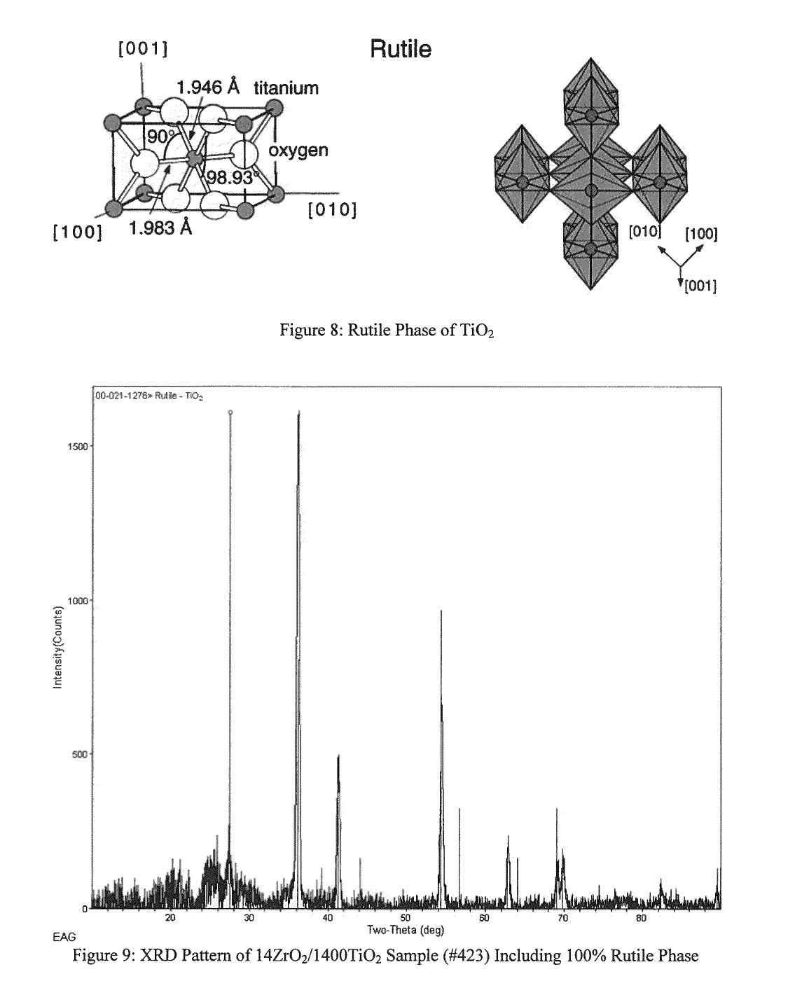

The data provided in FIG. 4A indicate that the ZrO₂ grows crystalline at a temperature of about 450 to 500° C. and that its lattice achieves appropriate regularity and an appropriate lattice constant at a thickness of about 1.0 nm. This crystal lattice promotes the growth of a preferentially-ordered, high-density layer of TiO₂ atop the layer of ZrO₂. X-ray diffraction data collected in a grazing incidence mode show that TiO₂, grown at temperatures of in the range of about 450 to 500° C. on a ZrO₂ seed layer, consists primarily of material in the rutile phase (FIG. 8).

With reference now to FIG. 8, there is shown a schematic diagram depicting the crystal structure of the rutile phase of TiO₂. The rutile phase of TiO₂ has a high packing density (4.274 g/cm³) and, consequently, the highest theoretically possible refractive index for TiO₂. The high packing density also reduces the tensile stress of the resulting film after it has cooled, when the film is deposited on a substrate having a lower coefficient of thermal expansion (CTE) than that of the film.

With reference now to FIG. 4B, there is shown a table setting forth measured and calculated data for several TiO₂/ZrO₂ coatings in accordance with the present invention, deposited on various substrates at a temperature of 475° C. For each coating, the data includes the combined thickness in nanometers of the ZrO₂ layers (t_{Z}); the calculated refractive index of the ZrO₂ layers at 633 nm (n_{Z}); the combined thickness in nanometers of the TiO₂ layers (t_{T}); the calculated refractive index of the TiO₂ layers at 633 nm (n_{T}); the combined thickness in nanometers of the ZrO₂ and TiO₂ layers (t_{TZ}); the composite refractive index of the ZrO₂ and TiO₂ layers at 633 nm (n_{TZ}); and the absorption coefficient of the combined ZrO₂ and TiO₂ layers (k_{TZ}).

The data from Run 374 provided in FIG. 4B indicate that a ZrO₂ seed layer of nine or more ALD cycles produces a TiO₂ layer having a high index of refraction, regardless of whether the TiO₂/ZrO₂ coating is deposited on a fused silica substrate (GE124), an aluminosilicate substrate (Corning 1737), or a D263 glass substrate. This indicates that ZrO₂ can be used as a seed layer for growing TiO₂ in the rutile phase on an arbitrary starting surface.

The data provided in FIG. 4B also indicate that the calculated refractive index of the TiO₂ layers at 633 nm may decrease as the thickness of the TiO₂ layers increases significantly beyond 80 nm. For example, in run 375 (where the thickness of the TiO₂ layers is about 150 nm), the calculated refractive index of the TiO₂ layers at 633 nm is less than it is in other runs (where the thickness of the TiO₂ layers is less than about 80 nm). The data thus indicate that, at thicknesses significantly beyond 80 nm, a less than optimal percentage of the TiO₂ layers is being deposited in the rutile phase. Each TiO₂ layer, therefore, preferably has a thickness less than 80 nm, or more preferably less than 20 nm, and most preferably less than 10 nm. One suitable approach for obtaining a greater TiO2 thickness while maintaining a high refractive index is suggested by run 379, wherein the TiO₂ layers are laminated at regular intervals with 15 ALD cycles of ZrO₂.

Thus, together, FIGS. 4A and 4B show that the number of ALD cycles for the ZrO₂ seed layer preferably is more than seven, more preferably is in the range of seven to 28, and most preferably is in the range of about 14 to about 18. It will be appreciated, however, that the invention also encompasses ZrO₂ seed layers formed using a number of ALD cycles outside these preferred ranges, if other process parameters are appropriately varied. The data set forth in FIGS. 4A and 4B apply to depositions performed using different ALD deposition tools, and it will be appreciated that the data do not precisely correlate with each other. Those skilled in the art, therefore, will appreciate that an optimum number of ALD cycles must be empirically determined based on the equipment and process parameters that are available.

With reference now to FIG. 5, there is shown a table setting forth measured and calculated data for several coatings deposited on various substrates. Each coating includes eight layers of TiO₂ and ZrO₂, with each layer having 14 ALD cycles of ZrO₂ followed by 165 ALD cycles of TiO₂, deposited at a temperature of 520° C. For each coating, the data includes the combined thickness in nanometers of the ZrO₂ layers (t_{Z}); the calculated refractive index of the ZrO₂ layers at 633 nm (n_{Z}); the combined thickness in nanometers of the TiO₂ layers (t_{T}); the calculated refractive index of the TiO₂ layers at 633 nm (n_{T}); the combined thickness in nanometers of the ZrO₂ and TiO₂ layers (t_{TZ}); the composite refractive index of the ZrO₂ and TiO₂ layers at 633 nm (n_{TZ}); and the absorption coefficient of the combined ZrO₂ and TiO₂ layers (k₆₃₃).

As shown in FIG. 5, the calculated refractive index of the TiO₂ layers is generally lower when the TiO₂/ZrO₂ film is deposited at a temperature of 520° C. than it is when the TiO₂/ZrO₂ film is deposited at a temperature of 475° C. This indicates that the optimal deposition temperature for this set of process conditions is less than 520° C. It is believed, however, that the TiO₂/ZrO₂ film can be grown at temperatures as low as 400° C. and as high as 550° C.

The data set forth in FIGS. 4A, 4B and 5 are for depositions produced in either a P400 tool or a P800 tool manufactured by Planar Oy (now Beneq Oy), of Espoo, Finland. The process conditions for producing the ZrO₂ layers included a repetition of the following cycle: a dose of H₂O followed by a nitrogen purge, and one or more successive doses of ZrCl₄, followed by a nitrogen purge. The ZrCl₄ was preheated to 250° C. The process conditions for producing the TiO₂ layers included a repetition of the following cycle: a dose of H₂O, a nitrogen purge of 1.5 seconds, a dose of TiCl₄, and a second nitrogen purge of 1.5 seconds. The TiCl₄ was kept at 23° C. A single dose of H₂O was supplied between the ZrO₂ and TiO₂ layers to provide full saturation of the surface with H₂O. The process may be expressed by the following formula:

N*(X*(H₂O+2*ZrCl₄)+H₂O+Y*(H₂O+TiCl₄)),
where N is the number of layers of TiO₂ and ZrO₂,
X is the number of cycles of ZrO₂ in each layer, and
Y is the number of cycles of TiO₂ in each layer.
   For example, the process for the depositions represented by the data set forth in FIG. 5 may be expressed by the following formula:

8*(14*(H₂O+2*ZrCl₄)+H₂O+165*(H₂O+TiCl₄)).

As shown in FIGS. 4A and 4B, the preferentially-ordered, rutile phase of the TiO₂ produced at a temperature of about 475° C., in conjunction with a ZrO₂ seed layer having more than 10 ALD cycles, exhibits low absorption and scattering. Absorption coefficients (k_{TZ}) from about 3.3×10⁻⁹ to about 7.2×10⁻⁹ were achieved for coatings having thicknesses of about 80 nm. The absorption coefficient was reduced by six orders of magnitude when the ZrO₂ seed layer was increased from seven ALD cycles (k_{TZ}=2.30×10⁻³) to 14 ALD cycles (k_{TZ}=3.30×10⁻⁹) in combination with 165 ALD cycles of TiO₂ on a fused silica substrate (FIG. 4A). The absorption coefficient for 1400 ALD cycles of TiO₂ with the addition of a seed layer of 14 ALD cycles of ZrO₂ (k_{TZ}=2.13×10⁻⁹) also was six orders of magnitude smaller than the absorption coefficient of 1400 ALD cycles of pure TiO₂ (k_{TZ}=3.26×10⁻³) (FIG. 4A).

An additional benefit of using ZrO₂ as a seed layer in place of other lamination materials such as Al₂O₃ is the relatively high refractive index of ZrO₂ (about 2.2 at 633 nm). Because ZrO₂ has a much higher refractive index than those of other lamination materials such as Al₂O₃ (about 1.644 at 633 nm), ZrO₂ is believed to have a less deleterious effect on the composite refractive index of the high-index layers of the resulting film.

ZrO₂, produced from ZrCl₄ and H₂O precursors, also has the advantage of being completely free of carbon contamination. Carbon contamination is often found in materials that are produced using metal-organic precursors, such as Al₂O₃, which can be produced from trimethylaluminium (Al₂(CH₃)₆) and H₂O precursors. Carbon can adversely affect a coating's absorption coefficient and the ability of the coating to operate at elevated temperatures.

The high-density rutile phase of TiO₂, which is produced according to the present invention, also exhibits good thermal stability. Good thermal stability can be important in some applications, such as infrared-reflective coatings for energy efficient halogen lamps.

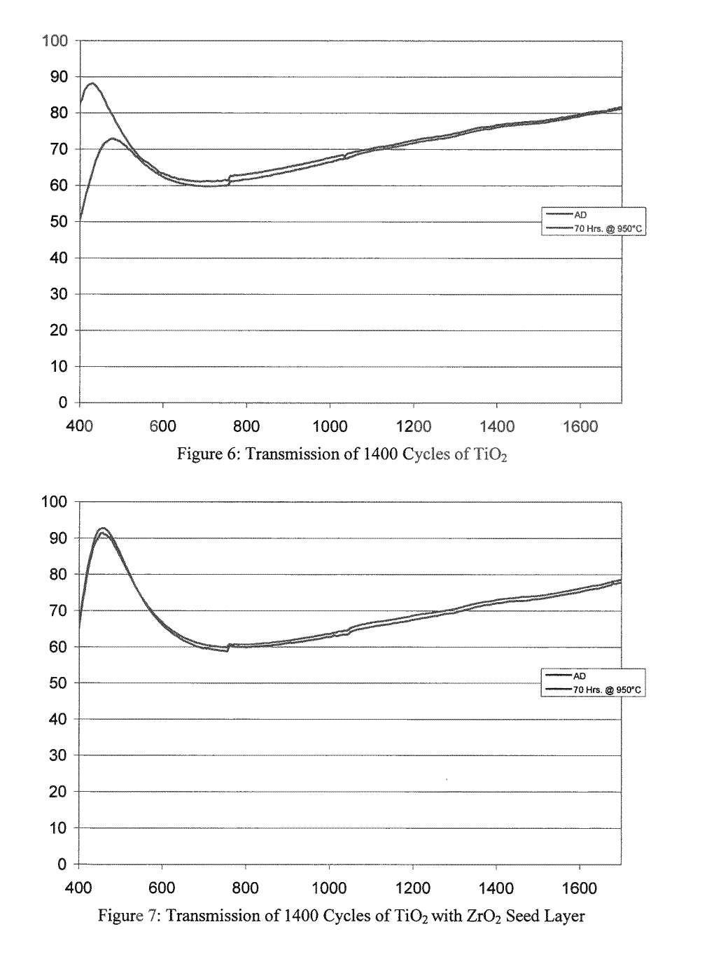

With reference now to FIG. 6, there is shown a graph depicting the optical transmission as a function of wavelength of 1400 ALD cycles of TiO₂ after deposition at 475° C. and after baking for 70 hours at 950° C. Similarly, FIG. 7 is a graph showing the optical transmission as a function of wavelength of 1400 ALD cycles of TiO₂ and 14 ALD cycles of ZrO₂ after deposition at 475° C. and after baking for 70 hours at 950° C.

As shown in FIGS. 6 and 7, the optical transmission at 450 nm of the pure TiO₂ decreases about 15.3 percent after baking for 70 hours at 950° C. In comparison, the optical transmission at 450 nm of the TiO₂ grown atop the ZrO₂ seed layer decreases only about 1.3 percent after baking for 70 hours at 950° C.

The rightmost column of FIG. 4A shows the percentage change in peak optical transmission after 70 hours of baking at 950° C. (ΔT). This percentage change is a metric for the thermal stability of the various depositions reflected in FIG. 4A. FIG. 4A shows that the best thermal stability coincides with the highest refractive index for TiO₂ and that this occurs in a deposition having 14 ALD cycles of ZrO₂. The worst thermal stability occurs in the pure TiO₂ deposition, which has no ALD cycles of ZrO₂. The optical losses in the pure TiO₂ are believed to result from scattering due to the growth of disordered crystalline structures. A TiO₂ film grown on a ZrO₂ seed layer according to the present invention has superior stability at elevated temperatures.

Other materials, such as hafnium dioxide (HfO₂), that produce a highly-ordered seed layer may be used in place of ZrO₂. HfO₂, like ZrO₂, has a valence state of +4 and can be deposited via ALD using hafnium tetrachloride (HfCl₄) and H₂O as precursors.

The present invention has been described above in terms of presently preferred embodiments so that an understanding of the present invention can be conveyed. However, there are other embodiments not specifically described herein for which the present invention is applicable. Therefore, the present invention should not to be seen as limited to the forms shown, which is to be considered illustrative rather than restrictive.

What is claimed is:

1. A thin film comprising:
a layer of seed material; and
a layer of titanium dioxide deposited on the layer of seed material;
wherein the seed material has a prescribed, uniform inter-atomic spacing adapted to cause the overlaying layer of titanium dioxide to be deposited in a primarily rutile phase.

2. The thin film of claim 1, wherein the seed material is selected from the group consisting of zirconium dioxide and hafnium dioxide.

3. The thin film of claim 1, wherein:
the seed material and titanium dioxide are deposited using a series of cycles in an atomic layer deposition (ALD) process; and
wherein the number of ALD cycles used to deposit the layer of seed material is at least about eight.

4. The thin film of claim 3, wherein the number of ALD cycles used to deposit the layer of seed material is in the range of about eight to about 28.

5. The thin film of claim 3, wherein the number of ALD cycles used to deposit the layer of seed material is in the range of about 14 to about 20.

6. The thin film of claim 1, wherein the layer of seed material has a thickness of at least about 0.5 nm.

7. The thin film of claim 1, wherein the layer of titanium dioxide has a thickness of less than about 80 nm.

8. The thin film of claim 1, wherein the layer of titanium dioxide has a thickness of less than about 20 nm.

9. The thin film of claim 1, wherein the layer of titanium dioxide has a thickness of less than about 10 nm.

10. The thin film of claim 1, wherein the thin film has a refractive index of at least 2.55 at a wavelength of 633 nm.

11. An optical filter comprising:
a substrate; and
an optical film deposited on the substrate, the optical film comprising a plurality of layers having a low refractive index interleaved with a plurality of layers having a high refractive index;
wherein each of the plurality of high refractive index layers comprises
a layer of seed material, and
a layer of titanium dioxide deposited on the layer of seed material,
wherein the seed material has a prescribed, uniform inter-atomic spacing adapted to cause the overlaying layer of titanium dioxide to be deposited in a primarily rutile phase.

12. The optical filter of claim 11, wherein each of the low refractive index layers comprises a material selected from the group consisting of silica, SiO₂:Al_{X}, and alumina.

13. A method for forming a thin film, comprising the steps of:
forming a layer of seed material having a prescribed, uniform inter-atomic spacing; and
forming a layer of titanium dioxide on the layer of seed material;
wherein the prescribed, uniform inter-atomic spacing of the seed material is adapted to cause the overlaying layer of titanium dioxide to be deposited in a primarily rutile phase.

14. The method of claim 13, and further comprising the step of selecting the seed material from the group consisting of zirconium dioxide and hafnium dioxide.

15. The method of claim 13, wherein the step of forming a layer of seed material comprises the step of depositing the seed material using at least eight cycles in an atomic layer deposition (ALD) process.

16. The method of claim 15, wherein the step of depositing the seed material comprises using between eight and 28 ALD cycles.

17. The method of claim 15, wherein the step of depositing the seed material comprises using between 14 and 18 ALD cycles.

18. The method of claim 13, wherein the step of forming a layer of seed material comprises forming a layer of seed material having a thickness of at least 0.5 nm.

19. The method of claim 13, wherein the layer of titanium dioxide has a thickness of less than about 80 nm.

20. The method of claim 13, wherein the layer of titanium dioxide has a thickness of less than about 20 nm.

21. The method of claim 13, wherein the layer of titanium dioxide has a thickness of less than about 10 nm.

22. The method of claim 13, wherein the method forms a thin film having a refractive index of at least 2.55, at a wavelength of 633 nm.

23. The method of claim 13, wherein
the step of forming a layer of seed material is performed at a temperature in the range of about 400 to about 550° C.; and
the step of forming a layer of titanium dioxide is performed at a temperature in the range of about 400 to about 550° C.

24. A method for forming an optical filter, comprising the steps of:
providing a substrate; and
depositing an optical film on the substrate, including a plurality of steps of depositing a layer of material having a low refractive index alternating with a plurality of steps of depositing a layer of material having a high refractive index;
wherein each of the plurality of steps of depositing a layer of material having a high refractive index comprises the steps of
depositing a layer of a seed material, and
depositing a layer of titanium dioxide onto the layer of seed material,
wherein the layer of seed material and the layer of titanium, together, comprise the layer of high refractive index material,
and wherein the layer of seed material has a prescribed, uniform inter-atomic spacing adapted to cause the overlaying layer of titanium dioxide to be deposited in a primarily rutile phase.

25. The method of claim 24, wherein:
each of the plurality of steps of depositing a layer of material having a high refractive index further comprises one or more additional steps of depositing a further layer of a seed material and a further layer of titanium dioxide onto the further layer of seed material; and
the layers of seed material and the layers of titanium dioxide, together, comprise the layer of high refractive index material.

26. The method of claim 24, and further comprising the step of selecting the layer of material having a low refractive index from the group consisting of silica, SiO₂:Al_{X}, and alumina.

27. A thin film comprising:
a layer of seed material; and
a layer of titanium dioxide deposited on the layer of seed material;
wherein the thin film has a refractive index of at least 2.55 and an absorption coefficient of at most 1×10⁻⁴, at a wavelength of 633 nm.

28. The thin film of claim 27, wherein the seed material is selected from the group consisting of zirconium dioxide and hafnium dioxide.

29. The thin film of claim 27, wherein:
the seed material and titanium dioxide are deposited using a series of cycles in an atomic layer deposition process; and
wherein the layer of seed material is deposited in at least 10 ALD cycles.

30. The thin film of claim 27, wherein the layer of seed material has a thickness of at least 0.5 nm.

31. The thin film of claim 27, wherein the titanium dioxide is configured primarily in the rutile phase.

32. An optical filter comprising:
a substrate; and
an optical film deposited on the substrate, the optical film comprising a plurality of layers having a low refractive index interleaved with a plurality of layers having a high refractive index;
wherein each of the plurality of high refractive index layers comprises
a layer of seed material, and
a layer of titanium dioxide deposited on the layer of seed material; and
wherein each of the plurality of high refractive index layers has a refractive index of at least 2.55 and an absorption coefficient of at most 1×10⁻⁴, at a wavelength of 633 nm.

33. The optical filter of claim 32, wherein each of the low refractive index layers comprises a material selected from the group consisting of silica, SiO₂:Al_{X}, and alumina.

34. A method for forming a thin film having a refractive index of at least 2.55 and an absorption coefficient of at most 1×10⁻⁴, at a wavelength of 633 nm, the method comprising:
forming a layer of a seed material; and
forming a layer of titanium dioxide on the layer of the seed material.

35. The method of claim 34, and further comprising the step of selecting the seed material from the group consisting of zirconium dioxide and hafnium dioxide.

36. The method of claim 34, wherein the step of forming a layer of seed material comprises the step of depositing the seed material using at least eight cycles in an atomic layer deposition (ALD) process.

37. The method of claim 36, wherein the step of depositing the seed material comprises using between eight and 28 ALD cycles.

38. The method of claim 36, wherein the step of depositing the seed material comprises using between 14 and 18 ALD cycles.

39. The method of claim 34, wherein the step of forming a layer of seed material comprises forming a layer of a seed material having a thickness of at least 0.5 nm.

40. The method claim 34, wherein the step of forming a layer of titanium dioxide comprises forming a layer of titanium dioxide have a thickness of less than 80 nm.

41. The method claim 34, wherein the step of forming a layer of titanium dioxide comprises forming a layer of titanium dioxide have a thickness of less than 20 nm.

42. The method claim 34, wherein the step of forming a layer of titanium dioxide comprises forming a layer of titanium dioxide have a thickness of less than 10 nm.

43. The method of claim 34, wherein the step of forming a layer of titanium dioxide comprises forming a layer of titanium dioxide primarily the rutile phase.

44. The method of claim 34, wherein
the step of forming a layer of seed material is performed at a temperature in the range of about 400 to about 550° C.; and
the step of forming a layer of titanium dioxide is performed at a temperature in the range of about 400 to about 550° C.

45. A method for forming an optical filter, comprising the steps of:
providing a substrate; and
depositing an optical film on the substrate, including a plurality of steps of depositing a layer of material having a low refractive index alternating with a plurality of steps of depositing a layer of material having a high refractive index;
wherein each of the plurality of steps of depositing a layer of material having a high refractive index comprises the steps of
depositing a layer of a seed material, and
depositing a layer of titanium dioxide onto the layer of seed material,
wherein the layer of seed material and the layer of titanium, together, comprise the layer of high refractive index material,
and wherein the layer of material having a high refractive index has a refractive index of at least 2.55 and an absorption coefficient of at most 1×10⁻⁴, at a wavelength of 633 nm.

46. The method of claim 45, wherein:
each of the plurality of steps of depositing a layer of material having a high refractive index further comprises one or more additional steps of depositing a further layer of a seed material and a further layer of titanium dioxide onto the further layer of seed material; and
the layers of seed material and the layers of titanium dioxide, together, comprise the layer of high refractive index material.

47. The method of claim 45, and further comprising the step of selecting the layer of material having a low refractive index from the group consisting of silica, SiO₂:Al_{X}, and alumina.

48. A method of manufacturing a composite structure, the composite structure comprising at least one layer of a first material (A) and at least one layer of a second material (B), the materials A and B having at least one common interface, the method comprising carrying out the following steps at a deposition temperature greater than 450° C.:
a) depositing a layer of material A to a thickness of at least 2 nm and at most 100 nm using an atomic layer deposition process;
b) depositing a layer of material B to a thickness less than the thickness of the material A layer using an atomic layer deposition process; and
optionally repeating steps a) and b) until a material of desired total thickness is obtained, the material having a total effective refractive index greater than 2.20 at a wavelength of 633 nm.

49. The method according to claim 48, wherein titanium chloride is used as a precursor.

50. The method according to claim 48, further comprising the step of depositing one or more layers of a material C, the refractive index of which is less than the combined refractive index of the layers of material A and material B.

51. The method according to claim 50, wherein material C is selected from the group consisting of silicon oxide and aluminum oxide.
